(19) United States
(12) Patent Application Publication
(10) Pub. No.: US 2025/0015779 A1
(43) Pub. Date: Jan. 9, 2025

(54) ACOUSTIC WAVE DEVICE

(71) Applicant: Murata Manufacturing Co., Ltd., Nagaokakyo-shi (JP)

(72) Inventors: Toru YAMAJI, Nagaokakyo-shi (JP); Sunao YAMAZAKI, Nagaokakyo-shi (JP); Hiroya SUZUKI, Nagaokakyo-shi (JP)

(21) Appl. No.: 18/897,222

(22) Filed: Sep. 26, 2024

Related U.S. Application Data
(63) Continuation of application No. PCT/JP2023/012689, filed on Mar. 28, 2023.
(60) Provisional application No. 63/329,903, filed on Apr. 12, 2022.
(60) Provisional application No. 63/324,438, filed on Mar. 28, 2022.

(51) Int. Cl. H03H 9/13; H03H 9/02

(52) U.S. Cl. CPC H03H 9/132; H03H 9/02015; H03H 9/02086; H03H 9/02228

(57) ABSTRACT

An acoustic wave device includes a support including a support substrate, a piezoelectric layer on the support in a first direction, a functional electrode on the piezoelectric layer, and a reinforcement film on the piezoelectric layer. The support includes a space portion that opens on a side of the piezoelectric layer, and an extended passage extending farther toward an outer side than an edge of the space portion in a second direction intersecting the first direction. A through-hole is provided at a position not overlapping the functional electrode in plan view in the first direction, communicates with the extended passage, and penetrates the piezoelectric layer. The reinforcement film is provided in a region between the through-hole and the space portion and overlaps at least a portion of a region where the piezoelectric layer and the extended passage overlap each other in the plan view.

### CROSS REFERENCE TO RELATED APPLICATIONS

This application claims the benefit of priority to Provisional Application No. 63/329,903 filed on Apr. 12, 2022 and Provisional Application No. 63/324,438 filed on Mar. 28, 2022, and is a Continuation Application of PCT Application No. PCT/JP2023/012689 filed on Mar. 28, 2023. The entire contents of each application are hereby incorporated herein by reference.

### BACKGROUND OF THE INVENTION

### 1. Field of the Invention

The present disclosure relates to acoustic wave devices.

### 2. Description of the Related Art

Japanese Unexamined Patent Application Publication No. 2012-257019 describes an acoustic wave device.

In the acoustic wave device disclosed in Japanese Unexamined Patent Application Publication No. 2012-257019, a through-hole may be provided in a piezoelectric layer for the purpose of etching a sacrificial layer for forming a space portion between a support substrate and the piezoelectric layer. In this case, displacement of the piezoelectric layer in a portion overlapping the space portion interferes with the displacement of the piezoelectric layer around the through-hole, and thus there is a possibility that cracks starting from the through-hole will be generated in the piezoelectric layer.

### SUMMARY OF THE INVENTION

Example embodiments of the present invention provide acoustic wave devices each of which reduces or prevents generation of cracks in the piezoelectric layer.

An acoustic wave device according to an example embodiment of the present invention includes a support including a support substrate, a piezoelectric layer provided in a first direction of the support, the first direction being a thickness direction of the support substrate, at least one functional electrode provided in the first direction of the piezoelectric layer, and a reinforcement film provided in the first direction of the piezoelectric layer. The support includes a space portion open on a side of the piezoelectric layer in the first direction, and an extended passage extending farther toward an outer side than an edge of the space portion in a second direction intersecting the first direction. At least one through-hole is provided at a position not overlapping the at least one functional electrode in plan view in the first direction, communicates with the extended passage, and penetrates into or through the piezoelectric layer. The reinforcement film is provided in a region between the through-hole and the space portion and overlaps at least a portion of a region where the piezoelectric layer and the extended passage overlap each other in plan view in the first direction.

According to example embodiments of the present invention, it is possible to reduce or prevent generation of cracks in the piezoelectric layer.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1A is a perspective view of an acoustic wave device according to a first example embodiment of the present invention.

FIG. 1B is a plan view illustrating an electrode structure according to the first example embodiment of the present invention.

FIG. 2 is a cross-sectional view of a portion taken along a line II-II of FIG. 1A.

FIG. 3A is a schematic cross-sectional view for explaining a Lamb wave propagating through a piezoelectric layer of a comparative example.

FIG. 3B is a schematic cross-sectional view for explaining a bulk wave in a thickness-shear primary mode propagating through the piezoelectric layer according to the first example embodiment of the present invention.

FIG. 4 is a schematic cross-sectional view for explaining an amplitude direction of the bulk wave in the thickness-shear primary mode propagating through the piezoelectric layer according to the first example embodiment of the present invention.

FIG. 5 is an explanatory diagram illustrating an example of resonance characteristics of the acoustic wave device according to the first example embodiment of the present invention.

FIG. 6 is an explanatory diagram illustrating a relationship between d/2p and a fractional bandwidth defining a resonator in the acoustic wave device according to the first example embodiment of the present invention where p is a center-to-center distance between adjacent electrodes or an average distance of the center-to-center distances and d is an average thickness of the piezoelectric layer.

FIG. 7 is a schematic plan view illustrating an example in which a pair of electrodes are provided in the acoustic wave device according to the first example embodiment of the present invention.

FIG. 8 is a reference diagram illustrating an example of resonance characteristics of the acoustic wave device according to the first example embodiment of the present invention.

FIG. 9 is an explanatory diagram illustrating a relationship between the fractional bandwidth and a phase rotation amount of spurious impedance normalized by about 180 degrees as an magnitude of a spurious level in the acoustic wave device according to the first example embodiment of the present invention when a large number of the acoustic wave resonators are provided.

FIG. 10 is an explanatory diagram illustrating a relationship between d/2p, a metallization ratio MR, and the fractional bandwidth.

FIG. 11 is an explanatory diagram illustrating a map of the fractional bandwidth with respect to Euler angles (0°, θ, ψ) of LiNbO₃ when d/p is made to approach 0 as much as possible.

FIG. 12 is a partially cutaway perspective view for explaining an acoustic wave device according to an example embodiment of the present invention.

FIG. 13 is a schematic plan view illustrating an example of the acoustic wave device according to the first example embodiment of the present invention.

FIG. 14 is a cross-sectional view taken along a line XIV-XV in FIG. 13.

FIG. 15 is a schematic plan view illustrating an example of an acoustic wave device according to a second example embodiment of the present invention.

FIG. 16 is a schematic plan view illustrating an example of an acoustic wave device according to a third example embodiment of the present invention.

FIG. 17 is a schematic plan view illustrating a first modified example of the acoustic wave device according to the third example embodiment of the present invention.

FIG. 18 is a schematic plan view illustrating a second modified example of the acoustic wave device according to the third example embodiment of the present invention.

FIG. 19 is a schematic plan view illustrating an example of an acoustic wave device according to a fourth example embodiment of the present invention.

FIG. 20 is a cross-sectional view taken along a line XX-XX of FIG. 19.

### DETAILED DESCRIPTION OF THE EXAMPLE EMBODIMENTS

Hereinafter, example embodiments of the present disclosure will be described in detail with reference to the accompanying drawings. The present invention is not limited to the example embodiments. Each example embodiment described in the present disclosure is merely an example, and in modified examples and second and subsequent example embodiments in which partial replacement or combination of configurations is possible between different example embodiments, description of matters common to a first example embodiment will be omitted, and only different points will be described. In particular, the same or similar functions and advantageous effects of the same or similar configurations will not be described in each of the example embodiments.

### First Example Embodiment

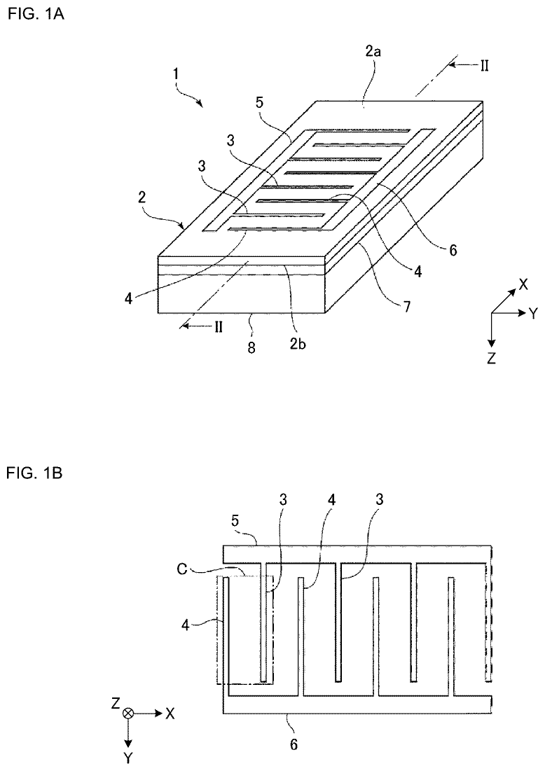

FIG. 1A is a perspective view illustrating an acoustic wave device according to a first example embodiment of the present invention. FIG. 1B is a plan view illustrating an electrode structure according to the first example embodiment.

An acoustic wave device 1 according to the first example embodiment includes a piezoelectric layer 2 made of, for example, LiNbO₃. The piezoelectric layer 2 may be made of LiTaO₃, for example. Cut-angles of LiNbO₃ and LiTaO₃ are a Z-cut in the first example embodiment. The cut-angles of LiNbO₃ or LiTaO₃ may be a rotated Y-cut or X-cut. A propagation orientation of, for example, Y propagation and X propagation±about 30° is preferable.

A thickness of the piezoelectric layer 2 is not particularly limited but is, for example, preferably about 50 nm or more and about 1000 nm or less in order to effectively excite a thickness-shear primary mode.

The piezoelectric layer 2 includes a first principal surface 2a and a second principal surface 2b opposed to each other in a Z direction. On the first principal surface 2a, an electrode finger 3 and an electrode finger 4 are provided.

Here, the electrode finger 3 is an example of a “first electrode finger”, and the electrode finger 4 is an example of a “second electrode finger”. In FIG. 1A and FIG. 1B, a plurality of the electrode fingers 3 is a plurality of the “first electrode fingers” connected to a first busbar 5. A plurality of the electrode fingers 4 is a plurality of the “second electrode fingers” connected to a second busbar 6. The plurality of electrode fingers 3 and the plurality of electrode fingers 4 are interdigitated with each other. Thus, an interdigital transducer (IDT) electrode including the electrode finger 3, the electrode finger 4, the first busbar 5, and the second busbar 6 is formed.

Each of the electrode finger 3 and the electrode finger 4 has a rectangular or substantially rectangular shape and has a length direction. The electrode finger 3 and the electrode finger 4 adjacent to the electrode finger 3 are opposed to each other in a direction orthogonal or substantially orthogonal to the length direction. The length direction of the electrode fingers 3 and 4 and the direction orthogonal or substantially orthogonal to the length direction of the electrode fingers 3 and 4 are directions intersecting a thickness direction of the piezoelectric layer 2. Therefore, it can be said that the electrode finger 3 and the electrode finger 4 adjacent to the electrode finger 3 are opposed to each other in a direction intersecting the thickness direction of the piezoelectric layer 2. In the following description, the thickness direction of the piezoelectric layer 2 may be referred to as the Z direction (or a first direction), the length direction of the electrode finger 3 and the electrode finger 4 may be referred to as a Y direction (or a second direction), and a direction orthogonal or substantially orthogonal to the length direction of the electrode finger 3 and the electrode finger 4 may be referred to as an X direction (or a third direction).

The length direction of the electrode finger 3 and the electrode finger 4 may be switched to the direction orthogonal or substantially orthogonal to the length direction of the electrode finger 3 and the electrode finger 4 illustrated in FIG. 1A and FIG. 1B. That is, in FIG. 1A and FIG. 1B, the electrode finger 3 and the electrode finger 4 may be extended in the direction in which the first busbar 5 and the second busbar 6 extend. In this case, the first busbar 5 and the second busbar 6 extend in the direction in which the electrode finger 3 and the electrode finger 4 extend in FIG. 1A and FIG. 1B. A plurality of pairs of the paired structure in which the electrode finger 3 connected to one potential and the electrode finger 4 connected to the other potential are adjacent to each other are provided in the direction orthogonal to the length direction of the electrode finger 3 and the electrode finger 4.

Here, the electrode finger 3 and the electrode finger 4 being adjacent to each other refers to a case where the electrode finger 3 and the electrode finger 4 are disposed with a gap interposed therebetween, not a case where the electrode finger 3 and the electrode finger 4 are disposed to be in direct contact with each other. When the electrode finger 3 and the electrode finger 4 are adjacent to each other, no electrode connected to a hot electrode or a ground electrode, including another electrode finger 3 and another electrode finger 4, is disposed between the electrode finger 3 and the electrode finger 4. The number of pairs is not necessarily an integer pair, and may be 1.5 pairs, 2.5 pairs, or the like.

A center-to-center distance between the electrode finger 3 and the electrode finger 4, that is, a pitch, is, for example, preferably in a range from about 1 μm to about 10 μm. The center-to-center distance between the electrode finger 3 and the electrode finger 4 is a distance connecting the center of a width dimension of the electrode finger 3 in the direction orthogonal or substantially orthogonal to the length direction of the electrode finger 3 and the center of a width dimension of the electrode finger 4 in the direction orthogonal or substantially orthogonal to the length direction of the electrode finger 4.

Further, when at least one of the electrode finger 3 and the electrode finger 4 is plural (in a case where there are 1.5 or more paired electrodes when the electrode finger 3 and the electrode finger 4 are one paired electrode), the center-to-center distance between the electrode finger 3 and the electrode finger 4 is an average value of each of the center-to-center distances between the adjacent electrode finger 3 and electrode finger 4 among 1.5 or more of the paired electrodes of the electrode finger 3 and the electrode finger 4.

Widths of the electrode finger 3 and the electrode finger 4, that is, dimensions of the electrode finger 3 and the electrode finger 4 in the opposing direction, are, for example, preferably in a range from about 150 nm to about 1000 nm. The center-to-center distance between the electrode finger 3 and the electrode finger 4 is a distance obtained by connecting the center of the dimension (width dimension) of the electrode finger 3 in the direction orthogonal or substantially orthogonal to the length direction of the electrode finger 3 and the center of the dimension (width dimension) of the electrode finger 4 in the direction orthogonal or substantially orthogonal to the length direction of the electrode finger 4.

In the first example embodiment, since the piezoelectric layer having a Z-cut is used, the direction orthogonal or substantially orthogonal to the length direction of the electrode finger 3 and the electrode finger 4 is orthogonal or substantially orthogonal to a polarization direction of the piezoelectric layer 2. This does not apply to the case when a piezoelectric material having a different cut-angle is used as the piezoelectric layer 2. Here, the term “orthogonal” is not limited to being strictly orthogonal and may be substantially orthogonal (an angle formed by the direction orthogonal to the length direction of the electrode finger 3 and the electrode finger 4 and the polarization direction is, for example, about 90°±10°).

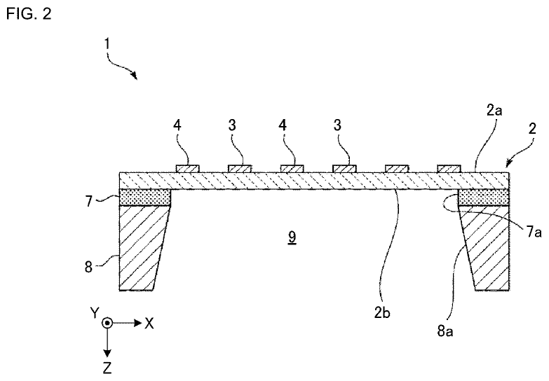

A support substrate 8 is laminated on a side of the second principal surface 2b of the piezoelectric layer 2 with an intermediate layer 7 interposed therebetween. The intermediate layer 7 and the support substrate 8 have a frame shape and include cavities 7a and 8a as illustrated in FIG. 2. Thus, a space portion (air gap) 9 is provided.

The space portion 9 is provided so as not to hinder vibration of an excitation region C of the piezoelectric layer 2. Therefore, the support substrate 8 is laminated on the second principal surface 2b with the intermediate layer 7 interposed therebetween at a position not overlapping a portion where at least one pair of the electrode finger 3 and the electrode finger 4 is provided. The intermediate layer 7 is not necessarily provided. Therefore, the support substrate 8 may be laminated directly or indirectly on the second principal surface 2b of the piezoelectric layer 2.

The intermediate layer 7 is made of silicon oxide, for example. However, the intermediate layer 7 can be made of, in addition to silicon oxide, an appropriate insulating material such as silicon nitride or alumina, for example.

The support substrate 8 is made of Si, for example. A plane orientation of Si on a surface of a side of the piezoelectric layer 2 may be (100), (110), or (111). Preferably, Si having a high resistivity of, for example, about 4 kΩ or more is desirable. However, the support substrate 8 may be made using an appropriate insulating material or an appropriate semiconductor material. Examples of the material of the support substrate 8 include piezoelectric materials such as aluminum oxide, lithium tantalate, lithium niobate, and quartz crystal, various ceramics such as alumina, magnesia, sapphire, silicon nitride, aluminum nitride, silicon carbide, zirconia, cordierite, mullite, steatite, and forsterite, dielectrics such as diamond and glass, and semiconductors such as gallium nitride.

The plurality of electrode fingers 3, the plurality of electrode fingers 4, the first busbar 5, and the second busbar 6 described-above are made of an appropriate metal or an appropriate alloy such as Al or an AlCu alloy, for example. In the first example embodiment, the electrode fingers 3, the electrode fingers 4, the first busbar 5, and the second busbar 6 have, for example, a structure in which an Al film is laminated on a Ti film. A close contact layer other than the Ti film may be used.

When driven, an AC voltage is applied between the plurality of electrode fingers 3 and the plurality of electrode fingers 4. More specifically, an AC voltage is applied between the first busbar 5 and the second busbar 6. Thus, it is possible to obtain resonance characteristics using a bulk wave in a thickness-shear primary mode excited in the piezoelectric layer 2.

In the acoustic wave device 1, when the thickness of the piezoelectric layer 2 is d and the center-to-center distance between any of the adjacent electrode finger 3 and electrode finger 4 among the plurality of pairs of the electrode finger 3 and the electrode finger 4 is p, d/p is, for example, about 0.5 or less. Therefore, the bulk wave in the thickness-shear primary mode described-above is effectively excited, and good resonance characteristics can be obtained. More preferably, d/p is, for example, about 0.24 or less, in this case, even better resonance characteristics can be obtained.

When at least one of the electrode finger 3 and the electrode finger 4 is plural as in the first example embodiment, that is, in a case where there are 1.5 or more paired electrodes when the electrode finger 3 and the electrode finger 4 are one paired electrode, the center-to-center distance between the adjacent electrode finger 3 and electrode finger 4 is an average distance of the center-to-center distance between each of the adjacent electrode finger 3 and electrode finger 4.

Since the acoustic wave device 1 according to the first example embodiment has the above-described configuration, even when the number of pairs of the electrode fingers 3 and the electrode fingers 4 is reduced in order to achieve miniaturization, a decrease in a Q value is unlikely to occur. This is because the resonator does not require reflectors on both sides and has small propagation loss. The reflector is not required because the bulk wave in the thickness-shear primary mode is used.

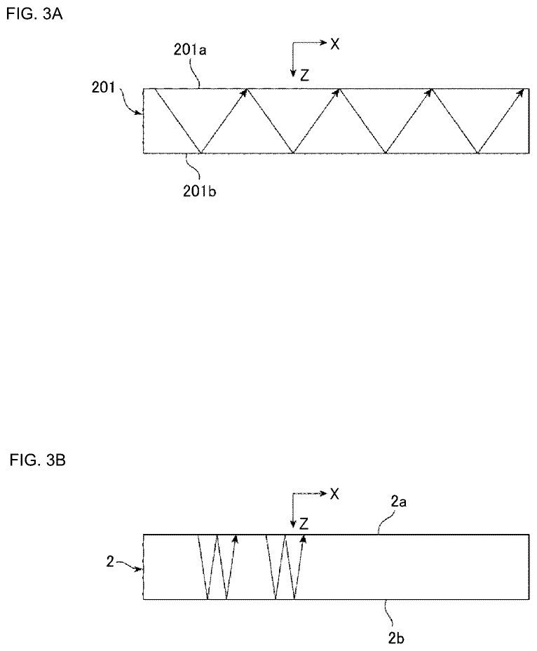

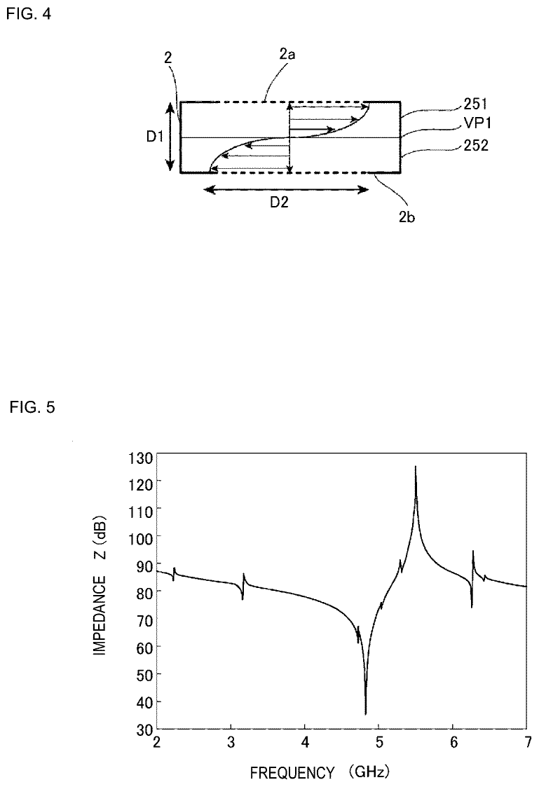

FIG. 3A is a schematic cross-sectional view for explaining a Lamb wave propagating through the piezoelectric layer of a comparative example. FIG. 3B is a schematic cross-sectional view for explaining the bulk wave in the thickness-shear primary mode propagating through the piezoelectric layer of the first example embodiment. FIG. 4 is a schematic cross-sectional view for explaining an amplitude direction of the bulk wave in the thickness-shear primary mode propagating through the piezoelectric layer of the first example embodiment.

In FIG. 3A, the acoustic wave device is as described in Japanese Unexamined Patent Application Publication No. 2012-257019, and the Lamb wave propagates through the piezoelectric layer. As illustrated in FIG. 3A, waves propagate in a piezoelectric layer 201 as indicated by arrows. The piezoelectric layer 201 includes a first principal surface 201a and a second principal surface 201b, and a thickness direction connecting the first principal surface 201a and the second principal surface 201b is the Z direction. The X direction is a direction in which the electrode fingers 3 and 4 of the IDT electrode are arranged. As illustrated in FIG. 3A, in the Lamb wave, the wave propagates in the X direction as illustrated in the figure. Although the piezoelectric layer 201 vibrates as a whole because of the plate wave, the wave propagates in the X direction, and thus reflectors are disposed on both sides to obtain the resonance characteristics. Therefore, propagation loss of the wave occurs, and when miniaturization is achieved, that is, when the number of pairs of the electrode fingers 3 and 4 is reduced, the Q value is decreased.

In contrast, as illustrated in FIG. 3B, in the acoustic wave device of the first example embodiment, the vibration is displaced in the thickness-shear direction, and thus the wave propagates substantially in the direction connecting the first principal surface 2a and the second principal surface 2b of the piezoelectric layer 2, that is, in the Z direction, and resonates. That is, an X direction component of the wave is significantly smaller than a Z direction component. Since the resonance characteristics are obtained by the propagation of the wave in the Z direction, no reflector is required. Thus, no propagation loss occurs when propagating to the reflector. Therefore, even when the number of electrode pairs each including the electrode finger 3 and the electrode finger 4 is reduced to achieve miniaturization, the decrease in the Q value is unlikely to occur.

As illustrated in FIG. 4, the amplitude direction of the bulk wave in the thickness-shear primary mode is opposite in a first region 251 included in the excitation region C (see FIG. 1B) and in a second region 252 included in the excitation region C of the piezoelectric layer 2. FIG. 4 schematically illustrates the bulk wave in a case where a voltage is applied between the electrode finger 3 and the electrode finger 4 such that the electrode finger 4 has a higher potential than the electrode finger 3. The first region 251 is a region of the excitation region C between the first principal surface 2a and a virtual plane VP1 that is orthogonal or substantially orthogonal to the thickness direction of the piezoelectric layer 2 and divides the piezoelectric layer 2 into two portions. The second region 252 is a region between the virtual plane VP1 and the second principal surface 2b in the excitation region C.

In the acoustic wave device 1, at least one pair of electrodes including the electrode finger 3 and the electrode finger 4 is provided, but since the wave is not propagated in the X direction, the number of electrode pairs including the electrode finger 3 and the electrode finger 4 is not necessarily plural. That is, it is sufficient that at least one electrode pair is provided.

For example, the electrode finger 3 is the electrode connected to a hot potential, and the electrode finger 4 is the electrode connected to a ground potential. However, the electrode finger 3 may be connected to the ground potential, and the electrode finger 4 may be connected to the hot potential. In the first example embodiment, as described above, at least one pair of electrodes is the electrode connected to the hot potential or the electrode connected to the ground potential, and no floating electrode is provided.

FIG. 5 is an explanatory diagram illustrating an example of the resonance characteristics of the acoustic wave device according to the first example embodiment. The design parameters of the acoustic wave device 1 that has obtained the resonance characteristics illustrated in FIG. 5 are as follows.
Piezoelectric layer 2: LiNbO₃ having Euler angles (0°, 0°, 90°)
Thickness of piezoelectric layer 2: about 400 nm
Length of excitation region C (see FIG. 1B): about 40 um
Number of pairs of electrodes including electrode finger 3 and electrode finger 4: 21 pairs
Center-to-center distance (pitch) between electrode finger 3 and electrode finger 4: about 3 μm
Widths of electrode finger 3 and electrode finger 4: about 500 nm
d/p: about 0.133
Intermediate layer 7: about 1 μm-thick silicon oxide film
Support substrate 8: Si

The excitation region C (see FIG. 1B) is a region where the electrode finger 3 and the electrode finger 4 overlap each other when viewed in the X direction orthogonal or substantially orthogonal to the length direction of the electrode finger 3 and the electrode finger 4. A length of the excitation region C is a dimension of the excitation region C along the length direction of the electrode finger 3 and the electrode finger 4. Here, the excitation region C is an example of an “intersecting region”.

In the first example embodiment, the center-to-center distances between the electrode pairs each including the electrode finger 3 and the electrode finger 4 are all equal or substantially equal in the plurality of pairs. That is, the electrode fingers 3 and the electrode fingers 4 are disposed at an equal or substantially equal pitch.

As is clear from FIG. 5, although the reflector is not provided, good resonance characteristics with a fractional bandwidth of about 12.5% is obtained.

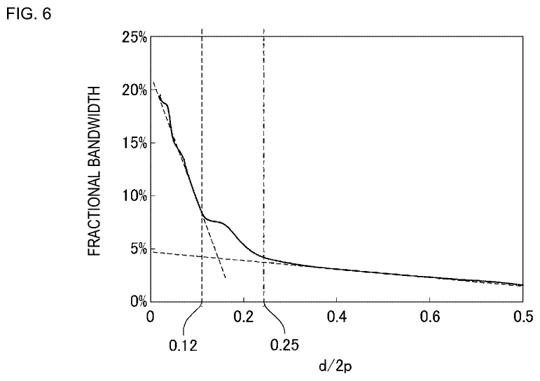

When the thickness of the piezoelectric layer 2 is d and the center-to-center distance between the electrode finger 3 and the electrode finger 4 is p, d/p is, for example, about 0.5 or less, and more preferably, for example, about 0.24 or less in the first example embodiment. This will be described with reference to FIG. 6.

A plurality of acoustic wave devices is obtained in the same manner as the acoustic wave device having the resonance characteristics illustrated in FIG. 5, except that d/2p is changed. FIG. 6 is an explanatory diagram illustrating a relationship between d/2p and the fractional bandwidth serving as a resonator in the acoustic wave device according to the first example embodiment, where p is the center-to-center distance between the adjacent electrodes or the average distance of the center-to-center distances, and d is the average thickness of the piezoelectric layer 2.

As illustrated in FIG. 6, when d/2p exceeds about 0.25, that is, when d/p>about 0.5, the fractional bandwidth is less than 5% even when d/p is adjusted. In contrast, when d/2p≤ about 0.25, that is, d/p≤ about 0.5, the fractional bandwidth can be increased to about 5% or more by changing d/p within the range, that is, a resonator having a high coupling coefficient can be provided. When d/2p is about 0.12 or less, that is, when d/p is about 0.24 or less, the fractional bandwidth can be increased to about 7% or more. In addition, when d/p is adjusted within this range, a resonator having a wider fractional bandwidth can be obtained, and a resonator having the higher coupling coefficient can be achieved. Therefore, it is understood that a resonator having the high coupling coefficient utilizing the bulk wave in the thickness-shear primary mode can be provided by setting d/p to about 0.5 or less.

Note that, at least one pair of electrodes may be one pair, and in a case of one pair of electrodes, the above p is the center-to-center distance between the adjacent electrode finger 3 and electrode finger 4. In a case of 1.5 or more pairs of electrodes, the average distance of the center-to-center distances between the adjacent electrode finger 3 and electrode finger 4 may be p.

In addition, when the piezoelectric layer 2 has variations in thickness, the thickness d of the piezoelectric layer 2 may adopt an average value of the thicknesses.

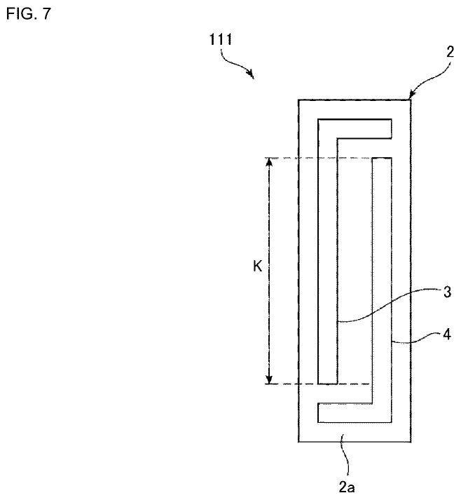

FIG. 7 is a schematic plan view illustrating an example in which a pair of electrodes are provided in the acoustic wave device according to the first example embodiment. In an acoustic wave device 111, a pair of electrodes including the electrode finger 3 and the electrode finger 4 are provided on the first principal surface 2a of the piezoelectric layer 2. In FIG. 7, K is an intersecting width. As described above, in the acoustic wave device according to the present example embodiment, the number of pairs of electrodes may be one. Even in this case, when the above d/p is about 0.5 or less, the bulk wave in the thickness-shear primary mode can be effectively excited.

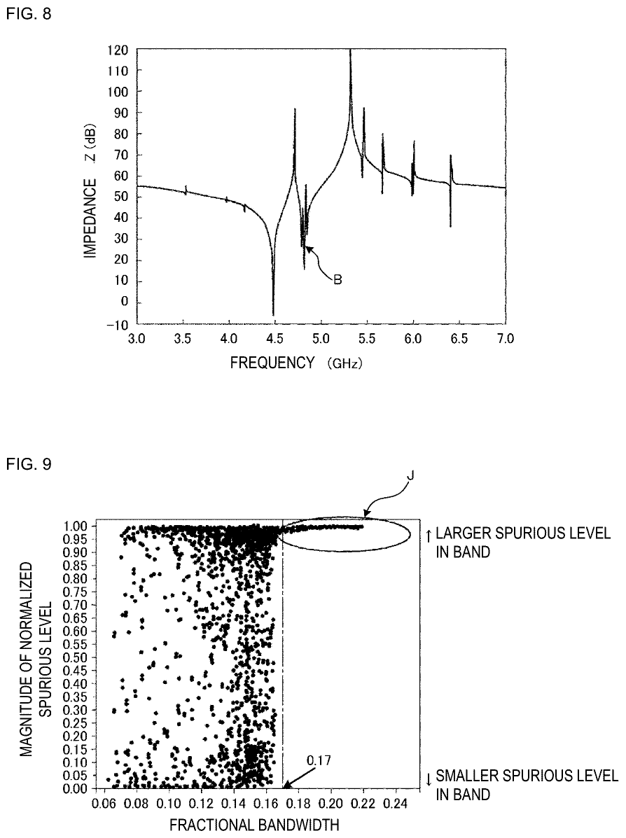

In the plurality of the electrode fingers 3 and the plurality of the electrode fingers 4 of the acoustic wave device 1, it is preferable that a metallization ratio MR of the adjacent electrode finger 3 and electrode finger 4 to the excitation region C, which is an overlapped region when viewed in the direction in which any of the adjacent electrode finger 3 and electrode finger 4 opposed to each other, satisfy MR≤ about 1.75 (d/p)+0.075, for example. In this case, a spurious level can be effectively reduced. This will be described with reference to FIG. 8 and FIG. 9.

FIG. 8 is a reference diagram illustrating an example of the resonance characteristics of the acoustic wave device according to the first example embodiment. Spurious components indicated by an arrow B appear between a resonant frequency and an anti-resonant frequency. d/p=about 0.08 and the Euler angles of LiNbO₃ are (0°, 0°, 90°). The above metallization ratio MR is set to about 0.35.

The metallization ratio MR will be explained with reference to FIG. 1B. In an electrode structure of FIG. 1B, when focusing on one pair of the electrode finger 3 and the electrode finger 4, it is assumed that only one pair of electrode finger 3 and electrode finger 4 is provided. In this case, a portion surrounded by a dot and dash line is the excitation region C. The excitation region C is a region of the electrode finger 3 overlapping the electrode finger 4, a region of the electrode finger 4 overlapping the electrode finger 3, and a region between the electrode finger 3 and the electrode finger 4 where the electrode finger 3 and the electrode finger 4 overlap each other when the electrode finger 3 and the electrode finger 4 are viewed in the direction orthogonal or substantially orthogonal to the length direction of the electrode finger 3 and the electrode finger 4, that is, in the opposing direction. An area of the electrode finger 3 and the electrode finger 4 in the excitation region C with respect to an area of the excitation region C is the metallization ratio MR. That is, the metallization ratio MR is the ratio of an area of the metallization portion to the area of the excitation region C.

When a plurality of pairs of electrode fingers 3 and electrode fingers 4 are provided, the ratio of the metallization portion included in the entire excitation region C to the total area of the excitation region C may be set as MR.

FIG. 9 is an explanatory diagram illustrating a relationship between the fractional bandwidth when a large number of acoustic wave resonators are provided, and a phase rotation amount of spurious impedance normalized by about 180 degrees as a magnitude of the spurious level in the acoustic wave device according to the first example embodiment. The fractional bandwidth is adjusted by changing a film thickness of the piezoelectric layer 2 and the dimension of the electrode finger 3 and the electrode finger 4. Further, FIG. 9 illustrates the results in the case of using the piezoelectric layer 2 made of LiNbO₃ having a Z-cut, but the same or substantially the same tendency is obtained in the case of using the piezoelectric layer 2 having a different cut-angle.

In the region surrounded by an ellipse J in FIG. 9, the spurious level is as large as about 1.0. As is clear from FIG. 9, when the fractional bandwidth exceeds about 0.17, that is, when the fractional bandwidth exceeds about 17%, a large spurious component having the spurious level equal to or more than about 1 appears in a pass band even when the parameters defining the fractional bandwidth are changed. That is, as in the resonance characteristics illustrated in FIG. 8, a large spurious component indicated by an arrow B appears in the band. Therefore, the fractional bandwidth is, for example, preferably about 17% or less. In this case, the spurious level can be reduced by adjusting the film thickness of the piezoelectric layer 2, the dimensions of the electrode finger 3 and the electrode finger 4, and the like.

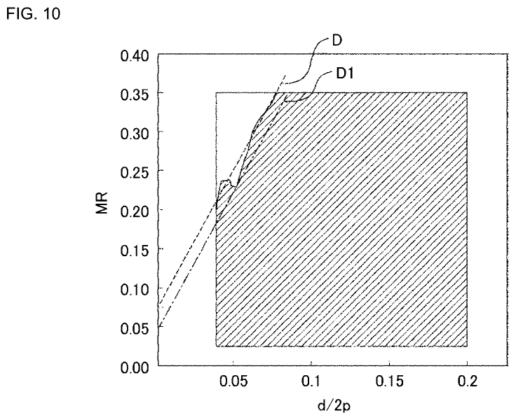

FIG. 10 is an explanatory diagram illustrating a relationship between d/2p, the metallization ratio MR, and the fractional bandwidth. In the acoustic wave device 1 according to the first example embodiment, various acoustic wave devices 1 having different d/2p and MR are formed, and the fractional bandwidth is measured. A hatched portion on the right side of a broken line D in FIG. 10 is a region where the fractional bandwidth is about 17% or less. A boundary between the hatched region and the non-hatched region is represented by MR=about 3.5 (d/2p)+0.075. That is, MR=about 1.75 (d/p)+0.075. Therefore, for example, preferably, MR≤ about 1.75 (d/p)+0.075. In this case, the fractional bandwidth is easily reduced to about 17% or less. The region on the right side of MR=about 3.5 (d/2p)+0.05 indicated by a dot and dash line DI in FIG. 10 is more preferable. That is, for example, when MR≤ about 1.75 (d/p)+0.05, the fractional bandwidth can be reliably reduced to about 17% or less.

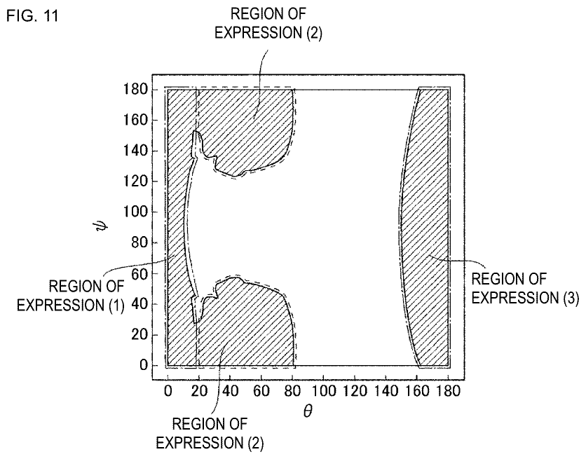

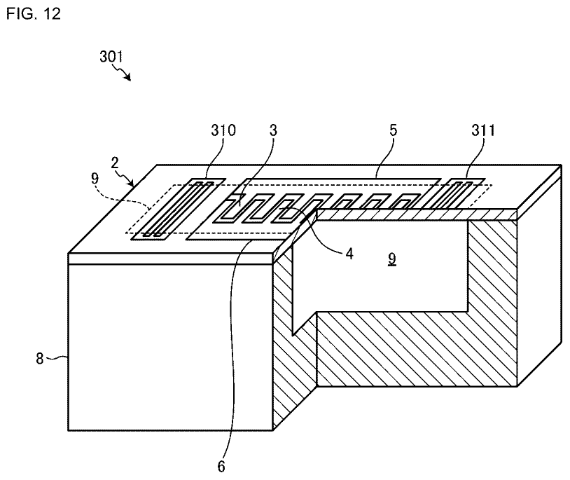

FIG. 11 is an explanatory diagram illustrating a map of the fractional bandwidth with respect to the Euler angles (0°, θ, ψ) of LiNbO₃ when d/p is made to approach 0 as much as possible. A hatched portion in FIG. 11 is a region where the fractional bandwidth of at least about 5% or more is obtained. When a range of the region is approximated, the range is represented by the following Expression (1), Expression (2), and Expression (3).

(0°±10°, 0° to 20°, arbitrary ψ) Expression (1)

(0°±10°,20° to 80°,0° to 60° (1−(θ−50)²/900)^{1/2}) or (0°±10°,20° to 80°,{180°−60°(1−(θ−50)²/900)^{1/2}} to 180°) Expression (2)

(0°±10°,{180°−30°(1−(ψ−90)²/8100)^{1/2}} to 180°, arbitrary ψ) Expression (3)

Therefore, the range of the Euler angles represented by the above Expression (1), Expression (2), or Expression (3) is preferable because the fractional bandwidth can be sufficiently widened.

FIG. 12 is a partially cutaway perspective view explaining an acoustic wave device according to an example embodiment of the present invention. In FIG. 12, an outer peripheral edge of the space portion 9 is indicated by a broken line. An acoustic wave device according to an example embodiment of the present invention may utilize a plate wave. In this case, as illustrated in FIG. 12, an acoustic wave device 301 includes reflectors 310 and 311. The reflectors 310 and 311 are provided on both sides of the electrode fingers 3 and 4 of the piezoelectric layer 2 in an acoustic wave propagation direction. In the acoustic wave device 301, an AC electric field is applied to the electrode fingers 3 and 4 above the space portion 9, and thus the Lamb wave as the plate wave is excited. At this time, since the reflectors 310 and 311 are provided on both sides, the resonance characteristics by the Lamb wave as the plate wave can be obtained.

As described above, the bulk wave in the thickness-shear primary mode is used in the acoustic wave devices 1 and 101. In the acoustic wave devices 1 and 101, the first electrode finger 3 and the second electrode finger 4 are adjacent electrodes, and d/p is, for example, about 0.5 or less, where d is the thickness of the piezoelectric layer 2 and p is the center-to-center distance between the first electrode finger 3 and the second electrode finger 4. Thus, even when the acoustic wave device is miniaturized, the Q value can be increased.

In the acoustic wave devices 1 and 101, the piezoelectric layer 2 is made of lithium niobate or lithium tantalate, for example. On the first principal surface 2a or the second principal surface 2b of the piezoelectric layer 2, there are the first electrode finger 3 and the second electrode finger 4 opposed to each other in a direction intersecting the thickness direction of the piezoelectric layer 2 and it is desirable to cover the first electrode finger 3 and the second electrode finger 4 with a protective film.

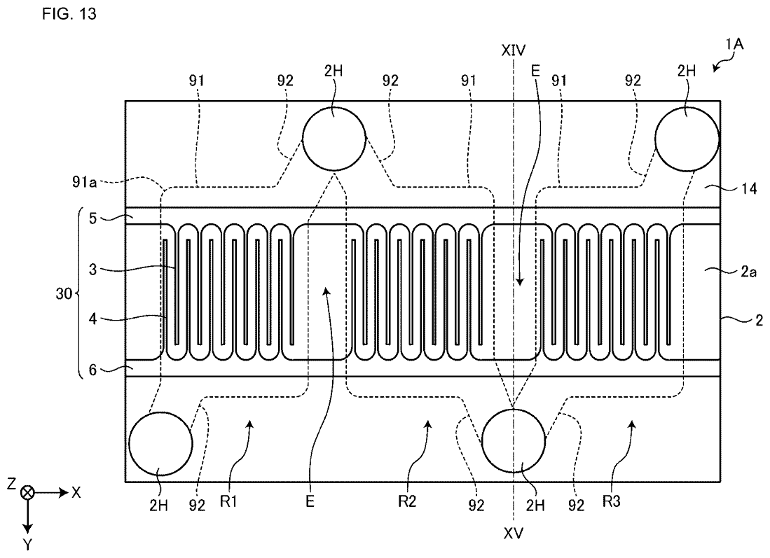

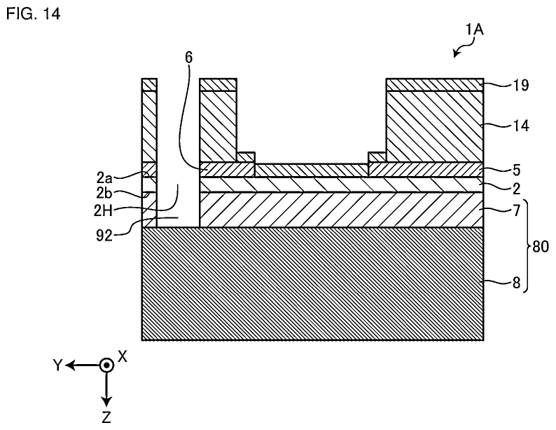

FIG. 13 is a schematic plan view illustrating an example of the acoustic wave device according to the first example embodiment. FIG. 14 is a cross-sectional view taken along a line XIV-XV in FIG. 13. As illustrated in FIG. 13 and FIG. 14, an acoustic wave device 1A according to the first example embodiment includes a support 80, the piezoelectric layer 2, a functional electrode 30, a reinforcement film 14, and a protective film 19.

As illustrated in FIG. 13, the acoustic wave device 1A according to the first example embodiment includes a plurality of resonators R1 to R3. In an example of FIG. 13, each of the plurality of resonators R1 to R3 includes one functional electrode 30.

The support 80 includes the support substrate 8. In the first example embodiment, the support 80 includes the intermediate layer 7 and the support substrate 8. The intermediate layer 7 is provided in the Z direction of the support substrate 8. The support 80 includes a space portion 91 and an extended passage 92.

The space portion 91 and the extended passage 92 are spaces that are open on the side of the piezoelectric layer 2 of the support 80. In the first example embodiment, the space portion 91 and the extended passage 92 are provided in the intermediate layer 7. In an example of FIG. 14, the space portion 91 and the extended passage 92 penetrate the intermediate layer 7 in the Z direction. That is, the space portion 91 and the extended passage 92 are spaces between the piezoelectric layer 2 and the support substrate 8. The space portion 91 and the extended passage 92 are not limited to penetrating through the intermediate layer 7 in the Z direction and may be spaces on the side of the piezoelectric layer 2 of the intermediate layer 7.

The space portion 91 is a space to not disturbing vibration of the excitation region of the resonators R1 to R3. In the first example embodiment, a plurality of the space portions 91 is provided to be arranged in the X direction. In the example of FIG. 13, each space portion 91 is provided at a position overlapping at least portions of the functional electrodes 30 of the resonators R1 to R3 in plan view in the Z direction.

In the first example embodiment, a shape of an edge of the space portion 91 is rectangular or substantially rectangular. Here, the edge of the space portion 91 refers to a boundary between a region overlapping the space portion 91 and a region not overlapping the space portion 91 in plan view in the Z direction. The shape of the edge of the space portion 91 being a rectangular or substantially rectangular means that the edge of the space portion 91 has two sides extending in the same direction and two sides extending in a direction orthogonal or substantially orthogonal to the sides, and includes, for example, a shape in which a vertex is rounded as illustrated in FIG. 13. In the example of FIG. 13, the shape of the space portion 91 is rectangular or substantially rectangular including edges in the Y direction (edges on both sides in the Y direction) and edges in the X direction (edges on both sides in the X direction). Hereinafter, a point on the edge of the space portion 91 closest to the intersection between the edge in the X direction and the edge in the Y direction of the space portion 91 or the intersection between an extension line of the edge in the X direction and an extension line of the edge in the Y direction of the space portion 91 will be described as a corner 91a. That is, the corner 91a is a point corresponding to the vertex of the rectangular or substantially rectangular shape of the space portion 91.

The extended passage 92 is a space extending to an outer side of the edge of the space portion 91 in the Y direction. In the first example embodiment, the extended passage 92 is a space extending to an outer side of the edge of the space portion 91 in the X direction. That is, the extended passage 92 is provided on each of both sides of the corner 91a of the space portion 91 opposed to each other in a direction parallel or substantially parallel to the Z direction. Thus, in the process of forming the space portion 91 in the manufacturing of the acoustic wave device 1A, an inflow path and an outflow path of an etchant for dissolving a sacrificial layer in the space portion 91 are linear, and thus the etchant can be easily injected and discharged.

The extended passage 92 communicates with the space portion 91. In the first example embodiment, at least one of the extended passages 92 communicates with another extended passage 92 that communicates with another space portion 91 adjacent to the space portion 91 with which the at least one of the extended passages 92 communicates. In other words, the space portions 91 adjacent to each other in the X direction communicate with each other by the connection of the two extended passages 92. In the example of FIG. 13, the extended passage 92 is connected to another extended passage 92 at an end portion on the opposite side to the space portion 91 in the Y direction. That is, the space portions 91 adjacent to each other in the X direction are connected to each other with the two extended passages 92 extending in the Y direction and connected to each other in a V shape interposed therebetween. Hereinafter, a position where the extended passages 92 are connected to each other may be described as a connection position.

The piezoelectric layer 2 is provided in the Z direction of the support 80. In the first example embodiment, the piezoelectric layer 2 is provided on a side of the intermediate layer 7 of the support 80. In the following description, the surface of the piezoelectric layer 2 on a side of the support 80 may be referred to as the second principal surface 2b, and the surface on the opposite side to the second principal surface 2b in the Z direction may be referred to as the first principal surface 2a.

The piezoelectric layer 2 includes a through-hole 2H. The through-hole 2H is a hole penetrating through the piezoelectric layer 2 in the Z direction. The through-hole 2H is provided at a position not overlapping the functional electrode 30 in plan view in the Z direction. In the example of FIG. 14, the through-hole 2H is provided so as not to overlap the functional electrode 30, the reinforcement film 14, and the protective film 19 in plan view in the Z direction. That is, in the example of FIG. 13, the support substrate 8 is exposed in plan view from the Z direction.

The through-hole 2H communicates with the extended passage 92 in the Z direction. In the first example embodiment, the through-hole 2H is positioned at an end portion of the extended passage 92 on the opposite side to the space portion 91 in the Y direction. Therefore, the through-hole 2H is connected to the space portion 91 with the extended passage 92 interposed therebetween. In the first example embodiment, a plurality of through-holes 2H is provided in each of the extended passages 92. In the example of FIG. 13, in plan view in the Z direction, the through-hole 2H is connected to another through-hole 2H in a straight line with the extended passage 92 and the space portion 91 interposed therebetween. Accordingly, a communication path between the through-holes 2H extends in the straight line, and thus, in the process of forming the space portion 91 by etching in the manufacturing of the acoustic wave device 1A, the etchant easily flows, and residues are unlikely to remain in the space portion 91.

In the first example embodiment, the through-hole 2H is provided at the connection position of the two extended passages 92. That is, the through-hole 2H communicates with the plurality of space portions 91. Thus, the through-hole 2H can be shared by the plurality of space portions 91, and thus the number of through-holes 2H can be reduced, and generation of cracks in the piezoelectric layer 2 caused by the through-hole 2H can be reduced or prevented. In the example of FIG. 13, the adjacent space portions 91 are connected to each other by a zigzag path whose direction is changed at the connection position of the extended passage 92 in plan view in the Z direction, and thus, in the process of forming the space portion 91 by etching in the manufacturing of the acoustic wave device 1A, the etchant easily flows and residues are unlikely to remain in the space portion 91.

The through-hole 2H is provided in the Y direction of a non-space region E. Here, the non-space region E refers to a region which is between the adjacent space portions 91 in the X direction and does not overlap the space portion 91 in plan view in the Z direction. That is, the space portion 91 is not present in the X direction and the Y direction of the through-hole 2H. Thus, the through-hole 2H and the space portion 91 are not adjacent to each other in the X direction and in the Y direction, and thus it is possible to further reduce or prevent the displacement of the piezoelectric layer 2 at a position overlapping the space portion 91 in plan view in the Z direction to interfere with the displacement of the piezoelectric layer 2 around the through-hole 2H, and to further reduce or prevent the generation of cracks in the piezoelectric layer 2.

The functional electrode 30 is the IDT electrode including electrode fingers 3 and 4 and busbars 5 and 6. In the example of FIG. 13, the functional electrode 30 is provided on the first principal surface 2a of the piezoelectric layer 2. In the example of FIG. 13, a plurality of the functional electrodes 30 is provided, and shares the busbars 5 and 6. That is, it can be said that the plurality of resonators R1 to R3 are resonators parallel or substantially parallel to each other.

The reinforcement film 14 is provided on a side of the first principal surface 2a with respect to the piezoelectric layer 2. The reinforcement film 14 is thicker than the electrode fingers 3 and 4. The reinforcement film 14 is provided in a region between the through-hole 2H and the space portion 91 in the Y direction in plan view in the Z direction to overlap at least a portion of a region where the piezoelectric layer 2 and the extended passage 92 overlap each other. In the first example embodiment, the reinforcement film 14 is provided to surround each through-hole 2H in plan view in the Z direction. Thus, since a region between the through-hole 2H and the space portion 91 is reinforced by the reinforcement film 14, it is possible to reduce or prevent the displacement of the piezoelectric layer 2 at the position overlapping the space portion 91 in plan view in the Z direction to interfere with the displacement of the piezoelectric layer 2 around the through-hole 2H, and to reduce or prevent the generation of cracks in the piezoelectric layer 2.

In the first example embodiment, the reinforcement film 14 is a metal layer and is made of, for example, an alloy of Al and Cu. The reinforcement film 14 is laminated on a portion of the busbars 5 and 6 of the functional electrode 30. Thus, the reinforcement film 14 can be electrically connected to the busbars 5 and 6, and by connecting the reinforcement film 14 to bumps or the like, the conductive wires to the functional electrode 30 can be led out to the outside of the acoustic wave device 1A.

The reinforcement film 14 is provided to overlap the corner 91a of the space portion 91 in plan view in the Z direction. In the example of FIG. 13, the reinforcement film 14 is provided to overlap the edge of the space portion 91 in the Y direction in plan view in the Z direction. This further mitigates concentration of stress on the piezoelectric layer 2, and thus further reduces or prevents the cracks in the piezoelectric layer 2.

The protective film 19 is a film provided on the functional electrode 30. The protective film 19 is made of, for example, silicon oxide. In the example of FIG. 14, the protective film 19 is provided on the first principal surface 2a of the piezoelectric layer 2, the functional electrode 30, and the reinforcement film 14.

As described above, the acoustic wave device 1A according to the first example embodiment includes the support 80 including the support substrate 8, the piezoelectric layer 2 provided in the first direction (Z direction) of the support 80, which is a thickness direction of the support substrate 8, at least one functional electrode 30 provided in the first direction of the piezoelectric layer 2, and the reinforcement film 14 provided in the first direction of the piezoelectric layer 2. The support 80 includes the space portion 91 that is open on the side of the piezoelectric layer 2 in the first direction, and the extended passage 92 that extends to the outer side of the edge of the space portion 91 in the second direction (Y direction) intersecting the first direction. There is at least one through-hole 2H that is disposed at a position not overlapping the functional electrode 30 in plan view in the first direction, and that communicates with the extended passage 92, and penetrates the piezoelectric layer 2. The reinforcement film 14 is provided in a region between the through-hole 2H and the space portion 91 to overlap at least a portion of a region where the piezoelectric layer 2 and the extended passage 92 overlap each other in plan view in the first direction. Thus, since the region between the through-hole 2H and the space portion 91 is reinforced by the reinforcement film 14, it is possible to reduce or prevent the displacement of the piezoelectric layer 2 at the position overlapping the space portion 91 in plan view in the Z direction to interfere with the displacement of the piezoelectric layer 2 around the through-hole 2H, and to reduce or prevent the generation of cracks in the piezoelectric layer 2.

As a preferable aspect, the functional electrode 30 is the IDT electrode including the plurality of first electrode fingers 3 extending in the second direction and the plurality of second electrode fingers 4 opposed to any one of the first electrode finger 3 in the plurality of first electrode fingers 3 in the third direction (X direction) orthogonal or substantially orthogonal to the second direction and extending in the second direction, and the reinforcement film 14 is a metal layer thicker than thicknesses of the first electrode finger 3 and the second electrode finger 4 in the first direction. Thus, the region between the through-hole 2H and the space portion 91 is reinforced by the reinforcement film 14, and thus it is possible to further reduce or prevent the displacement of the piezoelectric layer 2 at the position overlapping the space portion 91 in plan view in the Z direction to interfere with the displacement of the piezoelectric layer 2 around the through-hole 2H, and to further reduce or prevent the generation of cracks in the piezoelectric layer 2.

The IDT electrode may further include the first busbar 5 electrically connecting the plurality of first electrode fingers 3 and the second busbar 6 electrically connecting the plurality of second electrode fingers 4, and the reinforcement film 14 may be a metal layer provided to overlap a portion of the first busbar 5 and the second busbar 6. In this case, it is possible to reduce or prevent the displacement of the piezoelectric layer 2 at the position overlapping the space portion 91 in plan view in the Z direction to interfere with the displacement of the piezoelectric layer 2 around the through-hole 2H, and to reduce or prevent the generation of cracks in the piezoelectric layer 2.

As a preferable aspect, the plurality of IDT electrodes and a plurality of space portions 91 overlapping the respective IDT electrodes are further included, the adjacent space portions 91 communicate with each other by connecting two extended passages 92, and the through-hole 2H is positioned at the connection position where the two extended passages 92 are connected in plan view in the first direction.

As a preferable aspect, the plurality of IDT electrodes and the plurality of space portions 91 overlapping the respective IDT electrodes are further included, and the through-hole 2H is disposed in the second direction of the non-space region E between the adjacent space portions 91. Thus, the through-hole 2H and the space portion 91 are not adjacent to each other in the X direction and in the Y direction, and thus it is possible to further reduce or prevent the displacement of the piezoelectric layer 2 at a position overlapping the space portion 91 in plan view in the Z direction to interfere with the displacement of the piezoelectric layer 2 around the through-hole 2H, and to further reduce or prevent the generation of cracks in the piezoelectric layer 2.

As a preferable aspect, the space portion 91 has a rectangular or substantially rectangular shape in plan view in the first direction, and the reinforcement film 14 is provided to overlap the corner 91a of the space portion 91 in plan view in the first direction. This further mitigates the concentration of stress on the piezoelectric layer 2, and thus further reduces or prevents the cracks in the piezoelectric layer 2.

As a preferable aspect, when the thickness of the piezoelectric layer 2 is d and the center-to-center distance between the first electrode finger 3 and the second electrode finger 4 adjacent to each other is p, d/p is, for example, about 0.5 or less. Thus, the bulk wave in the thickness-shear primary mode can be effectively excited.

As a preferable aspect, d/p is, for example, about 0.24 or less. This allows the bulk wave in the thickness-shear primary mode to be more effectively excited.

As a preferable aspect, the acoustic wave device is configured to utilize the bulk wave in the thickness-shear mode. This improves the coupling coefficient and provides an acoustic wave device that can obtain good resonance characteristics.

As a preferable aspect, a region where the first electrode finger 3 and the second electrode finger 4 adjacent to each other overlap when viewed in a direction in which the first electrode finger 3 and the second electrode finger 4 opposed to each other is the excitation region, and when the metallization ratio of the plurality of first electrode fingers 3 and the plurality of second electrode fingers 4 with respect to the excitation region is MR, MR≤ about 1.75 (d/p)+0.075 is satisfied. This makes it possible to effectively reduce the spurious level.

As a preferable aspect, the piezoelectric layer 2 includes lithium niobate or lithium tantalate, and the Euler angles (φ, θ, ψ) of lithium niobate or lithium tantalate constituting the piezoelectric layer 2 are in the range of the following Expression (1), Expression (2), or Expression (3). In this case, the fractional bandwidth can be reliably reduced to about 17% or less.

$$( 0 ° \pm 10 ° , 0 ° to 20 ° , arbitrary ψ ) \qquad Expression ( 1 )$$

$$( 0 ° \pm 10 ° , 20 ° to 80 ° , 0 ° to 60 ° {( 1 - {( θ - 50 )}^{2} / 900 )}^{1 / 2} ) \qquad Expression ( 2 )$$

$$or$$

$$( 0 ° \pm 10 ° , 20 ° to 80 ° , \{ 180 ° - 60 ° {( 1 - {( θ - 50 )}^{2} / 900 )}^{1 / 2} \} to 180 ° )$$

$$Expression ( 3 )$$

$$( 0 ° \pm 10 ° , \{ 180 ° - 30 ° {( 1 - {( ψ - 90 )}^{2} / 8100 )}^{1 / 2} \} to 180 ° , arbitrary ψ )$$

### Second Example Embodiment

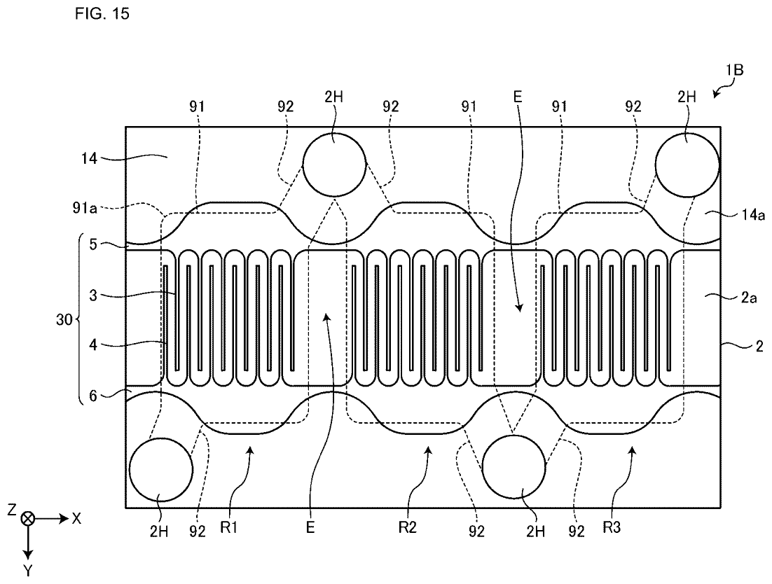

FIG. 15 is a schematic plan view illustrating an example of an acoustic wave device according to a second example embodiment of the present invention. As illustrated in FIG. 15, an acoustic wave device 1B according to the second example embodiment is different from the first example embodiment in that a reinforcement film 14 includes a protruding portion 14a. Hereinafter, the acoustic wave device according to the second example embodiment will be described with reference to the accompanying drawings, however, the same or corresponding portions as those in the first example embodiment are denoted by the same reference signs and will not be described.

The protruding portion 14a is a portion protruding into a non-space region E in plan view in a Z direction. That is, the protruding portion 14a is a portion of the reinforcement film 14 on a side of a functional electrode 30 in a Y direction. The protruding portion 14a overlaps a corner 91a of the space portion 91 in plan view in the Z direction. This mitigates the concentration of stress on a piezoelectric layer 2, thus reducing or preventing the cracks in the piezoelectric layer 2.

A shape of the protruding portion 14a is a partially curved shape. More specifically, an outer shape of the protruding portion 14a is the shape having a curve in which a portion thereof is convex toward the side opposite to the functional electrode 30 in the Y direction. In an example of FIG. 15, the outer shape of the protruding portion 14a is a bell-shaped curve (bell curve). More specifically, the outer shape of the protruding portion 14a is the curve in which the center in an X direction is convex toward the side of the functional electrode 30 in the Y direction, and both sides of the curve in the X direction are convex toward the side opposite to the functional electrodes 30 in the Y direction. Thus, the outer shape of the reinforcement film 14 and an edge of the space portion 91 are not orthogonal or substantially orthogonal to each other, and therefore, the concentration of stress on the piezoelectric layer 2 is further mitigated, and the cracks in the piezoelectric layer 2 can be further reduced or prevented.

As described above, in the acoustic wave device 1B according to the second example embodiment, the space portion 91 has a rectangular or substantially rectangular shape in plan view in a first direction, the reinforcement film 14 includes the protruding portion protruding toward the non-space region E, and the protruding portion 14a overlaps the corner 91a of the space portion 91 in plan view in the first direction. Even in this case, the concentration of stress on the piezoelectric layer 2 is also mitigated, and the cracks in the piezoelectric layer 2 can be reduced or prevented.

As a preferable aspect, the protruding portion 14a is partially curved in plan view in the first direction. Thus, the outer shape of the reinforcement film 14 and an edge of the space portion 91 are not orthogonal or substantially orthogonal to each other, and therefore, the concentration of stress on the piezoelectric layer 2 is further mitigated, and the cracks in the piezoelectric layer 2 can be further reduced or prevented.

### Third Example Embodiment

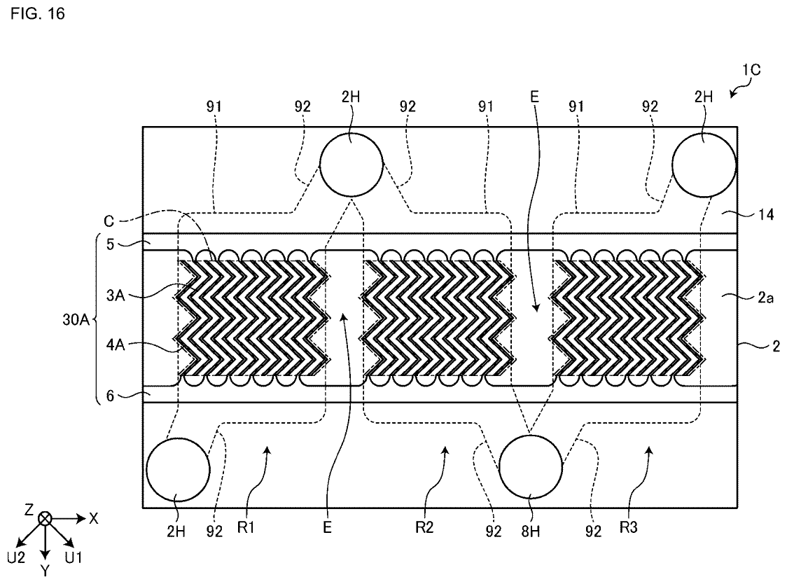

FIG. 16 is a schematic plan view illustrating an example of an acoustic wave device according to a third example embodiment of the present invention. As illustrated in FIG. 16, an acoustic wave device 1C according to the third example embodiment is different from the first example embodiment in that a functional electrode 30A includes meandering electrode fingers 3A and 4A. Hereinafter, the acoustic wave device 1C according to the third example embodiment will be described with reference to the accompanying drawings, however, the same or corresponding portions as those in the first example embodiment are denoted by the same reference signs and the description thereof will be omitted. Hereinafter, among end portions of the electrode fingers 3A and 4A in the Y direction, end portions connected to busbars 5 and 6 may be referred to as base ends, and end portions in the Y direction opposite to the base ends of the electrode fingers 3A and 4A may be explained as tip ends. In addition, a direction perpendicular or substantially perpendicular to a Z direction and intersecting an X direction and a Y direction may be described as a fourth direction U1, and a direction in which vector components in the X direction are opposite to those in the fourth direction U1 may be described as a fifth direction U2.

The electrode finger 3A is a first electrode finger having a meandering shape. The electrode finger 4A is a second electrode finger having a meandering shape. The meandering shape refers to extending between the base end and the tip end with alternating bends in one direction and the other direction with respect to a direction intersecting a straight line passing through the base end and the tip end. In the third example embodiment, the electrode fingers 3A and 4A are bent at least once from one side to the other side in the X direction between the base end and the tip end and are bent at least once from the other side to the one side in the X direction. In other words, the electrode fingers 3A and 4A extend in the fifth direction U2 after changing direction at the end extending in the fourth direction U1 at least once and extend in the fourth direction U1 after changing direction at the end extending in the fifth direction U2 at least once, between the base end and the tip end. Thus, even when the cracks are generated along side surfaces of the electrode fingers 3A and 4A of the piezoelectric layer 2, since the cracks have a long path to extend to the busbars 5 and 6, cutting and disconnection of the base ends of the electrode fingers 3A and 4A and the busbars 5 and 6 caused by the cracks reaching the busbars 5 and 6 and spreading in the X direction can be reduced or prevented.

In the third example embodiment, the length direction of the electrode fingers 3A and 4A refers to the direction along the straight line passing through the base end and the tip end, that is, the Y direction. Therefore, an excitation region C in the functional electrode 30A illustrated in FIG. 16 is a region of the electrode finger 3A overlapping the electrode finger 4A, a region of the electrode finger 4A overlapping the electrode finger 3A, and a region between the electrode finger 3A and the electrode finger 4A where the electrode finger 3A and the electrode finger 4A overlap each other, when the electrode finger 3A and the electrode finger 4A are viewed in the X direction orthogonal or substantially orthogonal to the Y direction which is the length direction of the electrode fingers 3A and 4A.

In an example of FIG. 16, a shape of the electrode fingers 3A and 4A is zigzag. That is, the electrode fingers 3A and 4A illustrated in FIG. 16, a straight line is defined between the points where the direction changes between the fourth direction U1 and the fifth direction U2.

The acoustic wave device 1C according to the third example embodiment has been described above, but the acoustic wave device according to the third example embodiment is not limited to the acoustic wave device illustrated in FIG. 16. Hereinafter, modified examples of example embodiments of the present invention will be described with reference to the accompanying drawings.

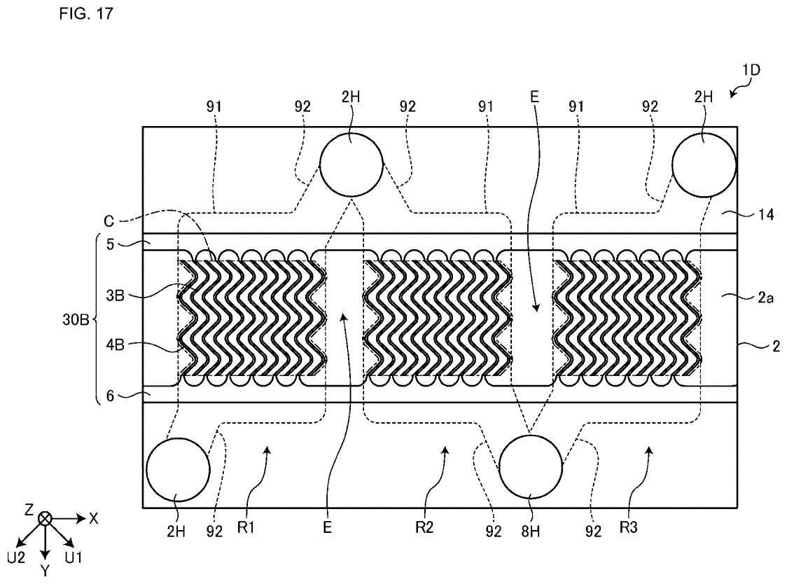

FIG. 17 is a schematic plan view illustrating a first modified example of the acoustic wave device according to the third example embodiment. As illustrated in FIG. 17, a shape of a first electrode finger 3B and the second electrode finger 4B according to the first modified example is wavy. That is, the electrode fingers 3B and 4B according to the first modified example include a curved line between points where the direction changes between the fourth direction U1 and the fifth direction U2. This can reduce or prevent the concentration of stress at the points where the direction changes between the fourth direction U1 and the fifth direction U2 of the electrode fingers 3B and 4B of the piezoelectric layer 2. In addition, since the cracks have a longer path to reach the busbars 5 and 6, cutting and disconnection of the base ends of the electrode fingers 3b and 4B and the busbars 5 and 6 caused by the cracks reaching the busbars 5 and 6 and spreading in the X direction can be reduced or prevented.

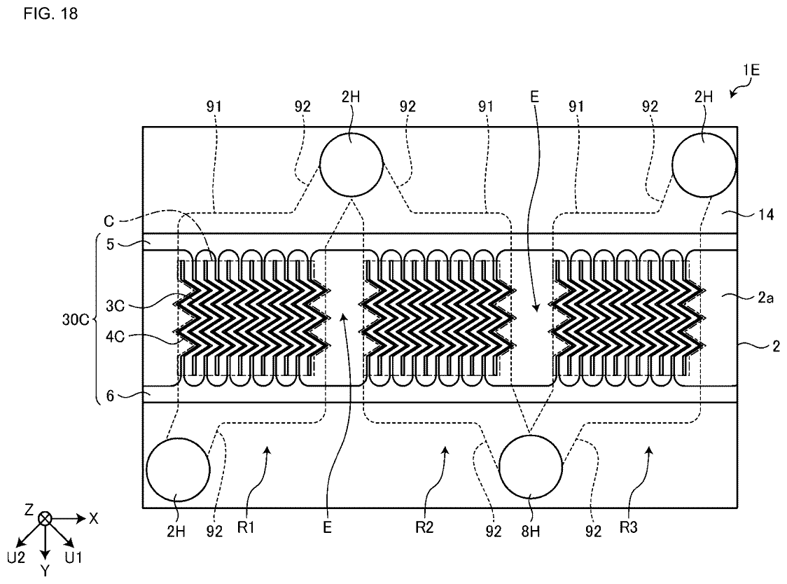

FIG. 18 is a schematic plan view illustrating a second modified example of the acoustic wave device according to the third example embodiment. As illustrated in FIG. 18, a first electrode finger 3C and a second electrode finger 4C according to the second modified example, portions including the base ends and portions including the tip ends extend in a second direction, and portions between the base end and the tip end in the Y direction are formed in a meandering shape. In other words, the electrode fingers 3C and 4C extend in a straight line in the Y direction from the base end, extend in the meandering shape, and then extend in a straight line in the Y direction to the tip end. As a result, since a shape of the electrode fingers 3C and 4C is the meandering shape only in a portion overlapping a center portion of the space portion 91 in the Y direction when viewed in plan view in the Z direction, in a case where the cracks are generated in the piezoelectric layer 2 at the portion overlapping the center portion of the space portion 91 in the Y direction where the cracks are likely to generate, the cracks have a long path to extend to the busbars 5 and 6 and disconnection of the electrode fingers 3C and 4C caused by the cracks extending the busbars 5 and 6 and spreading in the X direction can be reduced or prevented.

A length of the space portion 91 in the X direction may be larger than the length in the Y direction. In this case, although the cracks are likely to generate in a portion of the piezoelectric layer 2 overlapping the center portion of the space portion 91 in the Y direction in plan view in the Z direction, the functional electrode including meandering electrode fingers can reduce or prevent the electrode fingers from being disconnected.

As described above, in the acoustic wave device 1C according to the third example embodiment, the functional electrode 30A is an IDT electrode including a first busbar 5, a second busbar 6 opposed to the first busbar 5 in the second direction, the plurality of first electrode fingers 3 connected to the first busbar 5 at the base ends thereof and provided the tip ends in the second direction with respect to the first busbar 5, and the plurality of second electrode fingers 4 connected to the second busbar 6 at the base ends thereof and provided the tip ends in the second direction with respect to the second busbar 6, at least one electrode finger among the plurality of first electrode fingers 3 and the plurality of second electrode fingers 4 is the meandering electrode fingers 3A and 4A extending and bent alternately from one direction to the other direction in a third direction (X direction) intersecting to the second direction, the meandering electrode fingers 3A and 4A is bent at least once from one direction to the other direction in the third direction and at least once from the other direction to the one direction between the base end and the tip end. Thus, when the cracks are generated in the piezoelectric layer 2 at the end of the electrode fingers 3A or 4A in the X direction, even when the cracks spread in the extending direction of the electrode fingers 3A or 4A, the cracks stop spreading at the point where the electrode fingers 3A and 4A change direction in the X direction. Therefore, the cracks spread in the Y direction at the base ends of the electrode fingers 3A and 4A, and thus the disconnection of the electrode fingers 3A and 4A can be reduced or prevented.

A shape of the meandering electrode fingers 3A and 4A may be zigzag. Also, in this case, the spreading of the cracks can be reduced or prevented, and thus the disconnection of the electrode fingers 3A and 4A can be reduced or prevented.

As a preferable aspect, the shape of the meandering electrode fingers 3B and 4B is the shape of a wave. This can reduce or prevent the concentration of stress at the points where the direction changes between the fourth direction U1 and the fifth direction U2 of the electrode fingers 3B and 4B of the piezoelectric layer 2. In addition, since the cracks have a longer path to extend to the busbars 5 and 6, cutting and disconnection of the base ends of the electrode fingers 3B and 4B and the busbars 5 and 6 caused by the cracks reaching the busbars 5 and 6 and spreading in the X direction can be reduced or prevented.

The meandering electrode fingers 3C and 4C may include a portion including the base end and the tip end extending in the second direction. Also, in this case, the spreading of the cracks can be reduced or prevented, and thus the disconnection of the electrode fingers 3C and 4C can be reduced or prevented.

The length of the space portion 91 in the third direction may be greater than the length of the space portion 91 in the second direction. Even in this case, the spreading of the cracks can be reduced or prevented, and thus the disconnection of the electrode fingers 3C and 4C can be reduced or prevented.

### Fourth Example Embodiment

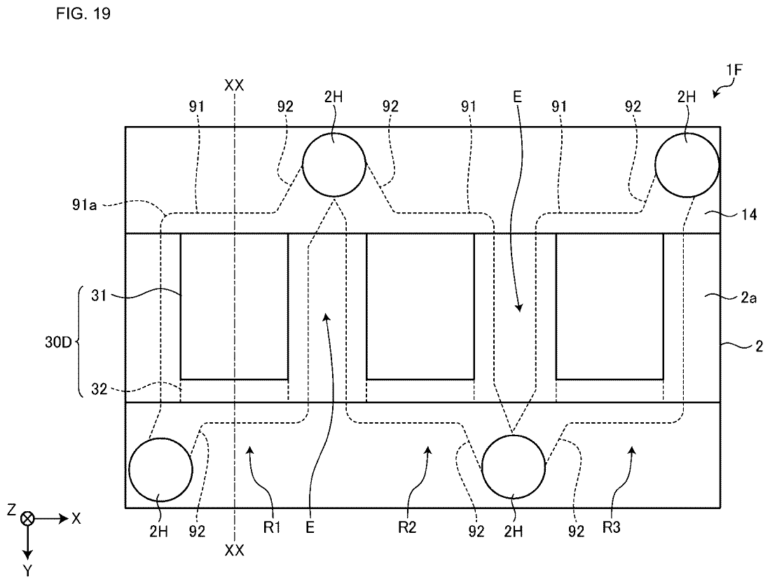

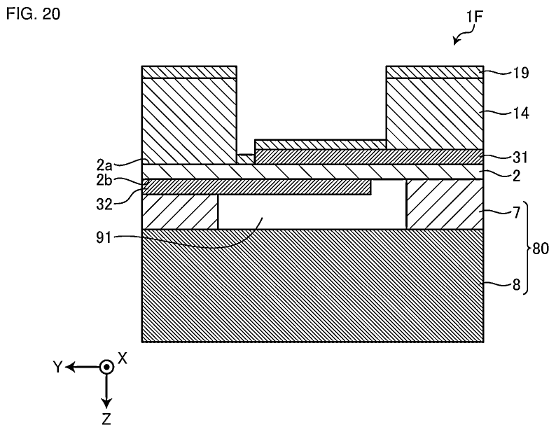

FIG. 19 is a schematic plan view illustrating an example of an acoustic wave device according to a fourth example embodiment of the present invention. FIG. 20 is a cross-sectional view taken along a line XX-XX of FIG. 19. An acoustic wave device 1F according to the fourth example embodiment is different from the first example embodiment in that it is a device that utilizes a bulk wave, that is, a bulk acoustic wave (BAW) element. Hereinafter, the acoustic wave device 1F according to the fourth example embodiment will be described with reference to the accompanying drawings, however, the same or corresponding portions as those in the first example embodiment are denoted by the same reference signs and the description thereof will be omitted.

In the fourth example embodiment, a piezoelectric layer 2 includes, for example, single crystal lithium niobate or lithium tantalate. This enables good use of the bulk wave.

In the fourth example embodiment, as illustrated in FIG. 19 and FIG. 20, a functional electrode 30D includes an upper electrode 31 and a lower electrode 32. The upper electrode 31 is a plate-shaped electrode provided on the first principal surface 2a of the piezoelectric layer 2. The lower electrode 32 is a plate-shaped electrode provided on the second principal surface 2b of the piezoelectric layer 2. In the fourth example embodiment, an excitation region refers to a region where the upper electrode 31 and the lower electrode 32 overlap each other in plan view in the Z direction. In an example of FIG. 20, the upper electrode 31 is provided between the first principal surface 2a of the piezoelectric layer 2 and the reinforcement film 14. The lower electrode 32 is provided between the second principal surface 2b of the piezoelectric layer 2 and the support 80.

In the fourth example embodiment, the reinforcement film 14 is provided on a side of the first principal surface 2a with respect to the piezoelectric layer 2 and on a side of the upper electrode 31 opposite the piezoelectric layer 2. The reinforcement film 14 is thicker than the upper electrode 31 and the lower electrode 32. This can reduce or prevent the generation of cracks in the piezoelectric layer 2.

As described above, in the acoustic wave device 1F according to the fourth example embodiment, the functional electrode 30D includes the upper electrode 31 provided on one principal surface (first surface principal 2a) of the piezoelectric layer 2 and the lower electrode 32 provided on the other principal surface (second principal surface 2b) of the piezoelectric layer 2. The piezoelectric layer 2 contains single crystal lithium niobate or lithium tantalate. The reinforcement film 14 is a metal layer thicker than thicknesses of the upper electrode 31 and the lower electrode 32 in the first direction. This can reduce or prevent the generation of cracks in the piezoelectric layer 2.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An acoustic wave device, comprising:
a support including a support substrate;
a piezoelectric layer provided in a first direction of the support being a thickness direction of the support substrate;
at least one functional electrode provided in the first direction of the piezoelectric layer; and
a reinforcement film provided in the first direction of the piezoelectric layer; wherein
the support includes a space portion that opens on a side of the piezoelectric layer in the first direction, and an extended passage extending farther toward an outer side than an edge of the space portion in a second direction intersecting the first direction;
at least one through-hole is provided at a position not overlapping the at least one functional electrode in plan view in the first direction, communicates with the extended passage, and penetrates into or through the piezoelectric layer; and
the reinforcement film is provided in a region between the through-hole and the space portion and overlaps at least a portion of a region where the piezoelectric layer and the extended passage overlap each other in plan view in the first direction.

2. The acoustic wave device according to claim 1, wherein the at least one functional electrode is an interdigital transducer (IDT) electrode including a plurality of first electrode fingers extending in the second direction and a plurality of second electrode fingers opposed to any one of the plurality of first electrode fingers in a third direction intersecting the second direction and extending in the second direction; and
the reinforcement film includes a metal layer thicker than thicknesses of the first electrode finger and the second electrode finger in the first direction.

3. The acoustic wave device according to claim 2, wherein
the IDT electrode further includes a first busbar electrically connecting the plurality of first electrode fingers and a second busbar electrically connecting the plurality of second electrode fingers; and
the reinforcement film includes a metal layer overlapping a portion of the first busbar and a portion of the second busbar.

4. The acoustic wave device according to claim 2, further comprising:
a plurality of the IDT electrodes; and
a plurality of the space portions overlapping the respective IDT electrodes; wherein
adjacent space portions of the plurality of space portions communicate with each other by two of the extended passages being connected, and the through-hole is provided at a connection position in which two of the extended passages are connected in plan view in the first direction.

5. The acoustic wave device according to claim 2, further comprising:
a plurality of the IDT electrodes; and
a plurality of the space portions overlapping the respective IDT electrodes; wherein
the through-hole extends in the second direction of a non-space region between adjacent space portions of the plurality of space portions.

6. The acoustic wave device according to claim 5, wherein
the space portion is rectangular or substantially rectangular in plan view in the first direction; and
the reinforcement film overlaps a corner of the space portion in plan view in the first direction.

7. The acoustic wave device according to claim 5, wherein
the space portion is rectangular or substantially rectangular in plan view in the first direction;
the reinforcement film includes a protruding portion protruding toward the non-space region; and
the protruding portion overlaps a corner of the space portion in plan view in the first direction.

8. The acoustic wave device according to claim 7, wherein the protruding portion is partially curved in plan view in the first direction.

9. The acoustic wave device according to claim 2, wherein when a film thickness of the piezoelectric layer is d and a center-to-center distance between the first electrode finger and the second electrode finger adjacent to each other is p, d/p is about 0.5 or less.

10. The acoustic wave device according to claim 9, wherein the d/p is about 0.24 or less.

11. The acoustic wave device according to claim 2, wherein the acoustic wave device is configured to utilize a bulk wave in a thickness-shear mode.

12. The acoustic wave device according to claim 2, wherein a region where the first electrode finger and the second electrode finger adjacent to each other overlap when viewed in a direction in which the first electrode finger and the second electrode finger opposed to each other is an excitation region, and when a metallization ratio of the plurality of first electrode fingers and the plurality of second electrode fingers with respect to the excitation region is MR, MR≤about 1.75 (d/p)+0.075 is satisfied.

13. The acoustic wave device according to claim 1, wherein
the at least one functional electrode includes an upper electrode on one principal surface of the piezoelectric layer and a lower electrode on another principal surface of the piezoelectric layer;
the piezoelectric layer includes single crystal lithium niobate or lithium tantalate; and
the reinforcement film includes a metal layer thicker than thicknesses of the upper electrode and the lower electrode in the first direction.

14. The acoustic wave device according to claim 2, wherein
the piezoelectric layer includes lithium niobate or lithium tantalate; and
Euler angles (φ, θ, ψ) of the lithium niobate or the lithium tantalate of the piezoelectric layer are in a range represented by Expression (1), Expression (2), or Expression (3):
$$( 0 ° \pm 10 ° , 0 ° to 20 ° , arbitrary ψ ) ; \qquad Expression ( 1 )$$
$$( 0 ° \pm 10 ° , 20 ° to 80 ° , 0 ° to 60 ° {( 1 - {( θ - 50 )}^{2} / 900 )}^{1 / 2} ) \qquad Expression ( 2 )$$
$$or$$
$$( 0 ° \pm 10 ° , 20 ° to 80 ° , \{ 180 ° - 60 ° {( 1 - {( θ - 50 )}^{2} / 900 )}^{1 / 2} \} to 180 ° ) ;$$
$$and$$
$$Expression ( 3 )$$
$$( 0 ° \pm 10 ° , \{ 180 ° - 30 ° {( 1 - {( ψ - 90 )}^{2} / 8100 )}^{1 / 2} \} to 180 ° , arbitrary ψ ) .$$

15. The acoustic wave device according to claim 1, wherein a thickness of the piezoelectric layer is about 50 nm or more and about 1000 nm or less.

16. The acoustic wave device according to claim 1, wherein a width of each of the plurality of first and second electrode fingers is in a range from about 150 nm to about 1000 nm.

17. The acoustic wave device according to claim 1, wherein the support includes an intermediate layer between the support substrate and the piezoelectric layer.

18. The acoustic wave device according to claim 17, wherein the intermediate layer includes silicon oxide.

19. The acoustic wave device according to claim 1, wherein the support substrate includes Si.

20. The acoustic wave device according to claim 19, wherein the Si has a resistivity of about 4 kΩ or more.
